(19) United States
(12) Patent Application Publication
(10) Pub. No.: US 2025/0374543 A1
(43) Pub. Date: Dec. 4, 2025

(54) SEMICONDUCTOR MEMORY DEVICES AND ELECTRONIC SYSTEMS INCLUDING THE SAME

(71) Applicant: Samsung Electronics Co., Ltd., Suwon-si (KR)

(72) Inventors: Hyeonpil JOO, Suwon-si (KR); JOONYOUNG KWON, Suwon-si (KR); JUNHYOUNG KIM, Suwon-si (KR); JIYOUNG KIM, Suwon-si (KR); SUKKANG SUNG, Suwon-si, Gyeonggi-do (KR); ByungChul LEE, Suwon-si, Gyeonggi-do (KR)

(21) Appl. No.: 18/989,860

(22) Filed: Dec. 20, 2024

(30) Foreign Application Priority Data
May 28, 2024 (KR) 10-2024-0069122

(51) Int. Cl. H10B 43/27; H01L 23/00; H01L 25/065; H01L 25/18; H10B 41/27; H10B 41/35; H10B 43/35; H10B 80/00

(52) U.S. Cl. CPC H10B 43/27; H01L 24/08; H01L 25/0657; H01L 25/18; H10B 41/27; H10B 41/35; H10B 43/35; H10B 80/00; H01L 2224/08145; H01L 2924/1431; H01L 2924/14511

(57) ABSTRACT

A semiconductor memory device includes a stacked structure comprising gate electrodes and interlayer insulating layers that are alternately stacked; a source structure on the stacked structure; and channel structures extending in the stacked. Each of the channel structures includes a core insulator that extends in the stacked structure in the vertical direction, wherein the core insulator protrudes into the source structure; a channel layer extending around the core insulator; and a gate dielectric layer extending around at least a portion of the channel layer, wherein a portion of the gate dielectric layer extends in a horizontal direction on the stacked structure. The source structure includes a first source part that is in contact with the channel structures and second source parts spaced apart from the channel structures by the first source part, wherein the first source part has a different crystal structure from the second source parts.

### CROSS-REFERENCE TO RELATED APPLICATIONS

This application claims the benefit under 35 USC § 119(a) of Korean Patent Application No. 10-2024-0069122, filed on May 28, 2024, in the Korean Intellectual Property Office, the entire disclosure of which is incorporated herein by reference for all purposes.

### BACKGROUND OF THE INVENTION

### 1. Technical Field

The disclosure relates to semiconductor devices, and more particularly to semiconductor memory devices and electronic systems including the same.

### 2. Description of Related Art

In an electronic system that requires data storage, there is a demand for a semiconductor memory device that is able to store a large volume of data. Accordingly, a method of increasing the data storage capacity of a semiconductor memory device has been researched. For example, as one of the methods of increasing the data storage capacity of a semiconductor memory device, a semiconductor memory device including three-dimensionally arranged memory cells instead of two-dimensionally arranged memory cells has been proposed. The above information may be presented as a related art to help with the understanding of the disclosure. No arguments or decisions are made as to whether any of the above is applicable as a prior art related to the disclosure.

### SUMMARY OF THE INVENTION

A technical goal of the present disclosure may be to provide a semiconductor memory device for mitigating the performance degradation of a drain saturation current and an electronic system including the same.

A technical goal of the present disclosure may be to provide a semiconductor memory device for mitigating a length discrepancy of each part in a vertical direction during a process of removing a gate dielectric layer and an electronic system including the same.

However, the goals to be achieved through the present disclosure are not limited to those described above, and additional goals not mentioned above may be clearly understood by one of ordinary skill in the art from the following description.

According to one embodiment, a semiconductor memory device includes a substrate; a bit line on an upper surface of the substrate; a stacked structure comprising a plurality of gate electrodes and a plurality of interlayer insulating layers that are alternately stacked in a vertical direction on the bit line; a source structure on the stacked structure; and a plurality of channel structures extending in the stacked structure and electrically connecting the source structure to the bit line, wherein each of the channel structures comprises: a core insulator in a channel hole that extends in the stacked structure in the vertical direction, wherein the core insulator protrudes into the source structure; a channel layer extending around the core insulator; and a gate dielectric layer extending around at least a portion of an outer surface of the channel layer, wherein a first portion of the gate dielectric layer extends in a horizontal direction on an upper surface of the stacked structure, wherein the source structure comprises: a first source part that is in contact with the channel structures; and a plurality of second source parts spaced apart from the channel structures by the first source part, wherein the first source part has a different crystal structure from the second source parts, wherein the horizontal direction is parallel with the upper surface of the substrate, and wherein the vertical direction is perpendicular to the upper surface of the substrate.

According to one embodiment, a semiconductor memory device includes a stacked structure comprising a plurality of gate electrodes and a plurality of interlayer insulating layers that are alternately stacked in a vertical direction; a source structure on the stacked structure; and a plurality of channel structures extending in the stacked structure, wherein each of the channel structures comprises: a core insulator extending in the stacked structure in the vertical direction, wherein the core insulator protrudes into the source structure; a channel layer extending around the core insulator; and a gate dielectric layer on an outer surface of the channel layer, wherein the gate dielectric layer includes a first portion between an upper surface of the stacked structure and the source structure in the vertical direction and a second portion overlapping the stacked structure in a horizontal direction that is perpendicular to the vertical direction, wherein the source structure comprises: a first source part that is in contact with the channel structures; and a plurality of second source parts spaced apart from the channel structures by the first source part, wherein the first source part extends around the second source parts, and wherein the first source part has a different crystal structure from the second source parts.

According to one embodiment, an electronic system includes a semiconductor device that includes an input/output pad electrically connected to a peripheral circuit; and a controller which controls the semiconductor device and is electrically connected through the input/output pad to the semiconductor device; wherein the semiconductor device includes: a substrate; a bit line on an upper surface of the substrate; a stacked structure comprising a plurality of gate electrodes and a plurality of interlayer insulating layers that are alternately stacked in a vertical direction on the bit line; a source structure on the stacked structure; and a plurality of channel structures extending in the stacked structure and electrically connecting the source structure to the bit line, wherein each of the channel structures comprises: a core insulator in a channel hole that extends in the stacked structure in the vertical direction, wherein the core insulator protrudes into the source structure; a channel layer extending around the core insulator; and a gate dielectric layer extending around at least a portion of an outer surface of the channel layer, wherein a first portion of the gate dielectric layer extends in a horizontal direction on an upper surface of the stacked structure, wherein the source structure comprises: a first source part that is in contact with the channel structures; and a plurality of second source parts spaced apart from the channel structures by the first source part, wherein the first source part has a different crystal structure from the second source parts, wherein the horizontal direction is parallel with the upper surface of the substrate, and wherein the vertical direction is perpendicular to the upper surface of the substrate.

### BRIEF DESCRIPTION OF THE DRAWINGS

The foregoing and other aspects, features, and advantages of certain embodiments in the disclosure will become apparent from the following detailed description with reference to the accompanying drawings.

FIG. 1 is a diagram schematically illustrating an electronic system including a semiconductor memory device according to an embodiment.

FIG. 2 is a perspective view schematically illustrating an electronic system including a semiconductor memory device according to an embodiment.

FIGS. 3 and 4 are cross-sectional views of a semiconductor package including a semiconductor memory device according to an embodiment, and correspond to cross-sections cut along a line I-I′ and a line II-II′ of FIG. 2, respectively.

FIG. 5 is an example of a cross-sectional view of a semiconductor memory device, and corresponds to an area A of FIG. 3.

FIG. 6 is an example of a partial cross-sectional view of a semiconductor memory device, and corresponds to an area B of FIG. 5.

FIG. 7 is an example of a partial cross-sectional view of a semiconductor memory device, and corresponds to an area B of FIG. 5.

FIG. 8 is an example of a partial cross-sectional view of a semiconductor memory device, and corresponds to an area B of FIG. 5.

FIGS. 9A, 9B, 9C, 9D, 9E, and 9F are schematic cross-sectional views illustrating a process of forming a semiconductor memory device according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like constituent elements and a repeated description related thereto may be omitted. In the description of embodiments, detailed description of well-known related structures or functions may be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the embodiments described above and an element having a common function. Unless otherwise mentioned, the descriptions on the embodiments may be applicable to the following embodiments and thus, duplicated descriptions may be omitted for conciseness.

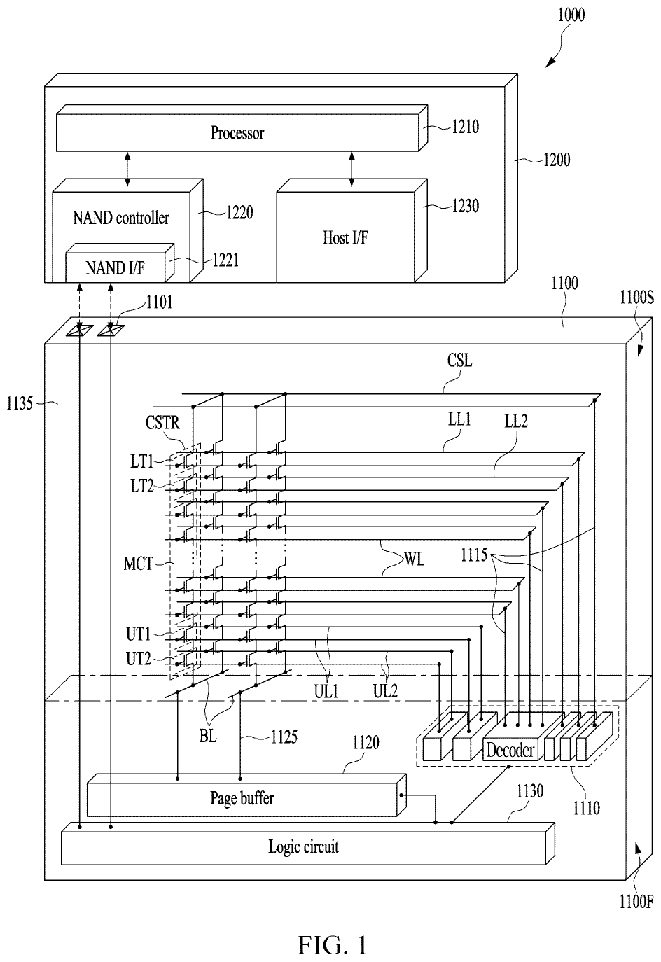

FIG. 1 is a diagram schematically illustrating an electronic system including a semiconductor memory device according to an embodiment.

Referring to FIG. 1, an electronic system 1000 according to an embodiment may include a semiconductor memory device 1100 and a controller 1200 electrically connected to the semiconductor memory device 1100. The electronic system 1000 may be a storage device including at least one semiconductor memory device 1100 or an electronic device including the storage device. For example, the electronic system 1000 may be a solid-state drive (SSD) device, a Universal Serial Bus (USB) device, a computing system, a medical device, or a communication device, each of which includes at least one semiconductor memory device 1100.

The semiconductor memory device 1100 may be a non-volatile memory device. For example, the semiconductor memory device 1100 may be a three-dimensional (3D) not-and (NAND) flash memory device as described below. The semiconductor memory device 1100 may include a first area 1100F and a second area 1100S. The first area 1100F may be a peripheral circuit area including a decoder circuit 1110, a page buffer 1120, and a logic circuit 1130. The second area 1100S may be a memory cell area including bit lines BL, a common source line CSL, word lines WL, first lines LL1 and LL2, second lines UL1 and UL2, and memory cell strings CSTR between the bit lines BL and the common source line CSL. The second area 1100S may be disposed on the first area 1100F, but unlike the drawings, the second area 1100S may be disposed adjacent to the first area 1100F.

In the second area 1100S, each of the memory cell strings CSTR may include first transistors LT1 and LT2 disposed adjacent to the common source line CSL, second transistors UT1 and UT2 disposed adjacent to the bit lines BL, and a plurality of memory cell transistors MCT disposed between the first transistors LT1 and LT2 and the second transistors UT1 and UT2. The number of first transistors LT1 and LT2 and the number of second transistors UT1 and UT2 may vary depending on the embodiments. The memory cell strings CSTRs may be disposed between the common source line CSL and the first area 1100F.

The first transistors LT1 and LT2 may include a ground selection transistor. The second transistors UT1 and UT2 may include a string select transistor. The first lines LL1 and LL2 may be gate electrodes of the first transistors LT1 and LT2. The word lines WL may be gate electrodes of the memory cell transistors MCTs. The second lines UL1 and UL2 may be gate electrodes of the second transistors UT1 and UT2.

The first transistors LT1 and LT2 may include a first erase control transistor LT1 and a ground selection transistor LT2 that are (electrically) connected in series. The second transistors UT1 and UT2 may include a string selection transistor UT1 and a second erase control transistor UT2 that are (electrically) connected in series. At least one of the first erase control transistor LT1 and the second erase control transistor UT2 may be used for an erasure operation of deleting data stored in the memory cell transistors MCT using a gate induced drain leakage (GIDL) phenomenon.

The common source line CSL, the first lines LL1 and LL2, the word lines WL, and the second lines UL1 and UL2 may be electrically connected to the decoder circuit 1110 through first connection wires 1115 extending from the first area 1100F to the second area 1100S. The bit lines BL may be electrically connected to a page buffer 1120 through second connection wires 1125 extending from the first area 1100F to the second area 1100S.

In the first area 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 through an input/output connection wire 1135 extending from the first area 1100F to the second area 1100S.

The controller 1200 may include a processor 1210, a NAND controller 1220, and a host interface 1230. Depending on the embodiment, the electronic system 1000 may include one or more semiconductor memory devices 1100, and the controller 1200 may control one or more semiconductor memory devices 1100.

The processor 1210 may control the overall operation of the electronic system 1000 including the controller 1200. The processor 1210 may operate by set firmware, and may access the semiconductor memory device 1100 by controlling the NAND controller 1220. The NAND controller 1220 may include a NAND interface 1221 that processes communication with the semiconductor memory device 1100. Through the NAND interface 1221, a control command to control the semiconductor memory device 1100, data to be written to the memory cell transistors MCT of the semiconductor memory device 1100, or data to be read from the memory cell transistors MCT of the semiconductor memory device 1100 may be transmitted. The host interface 1230 may provide a communication function between the electronic system 1000 and an external host. When a control command is received through the host interface 1230 from an external host, the processor 1210 may control the semiconductor memory device 1100 in response to the received control command. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

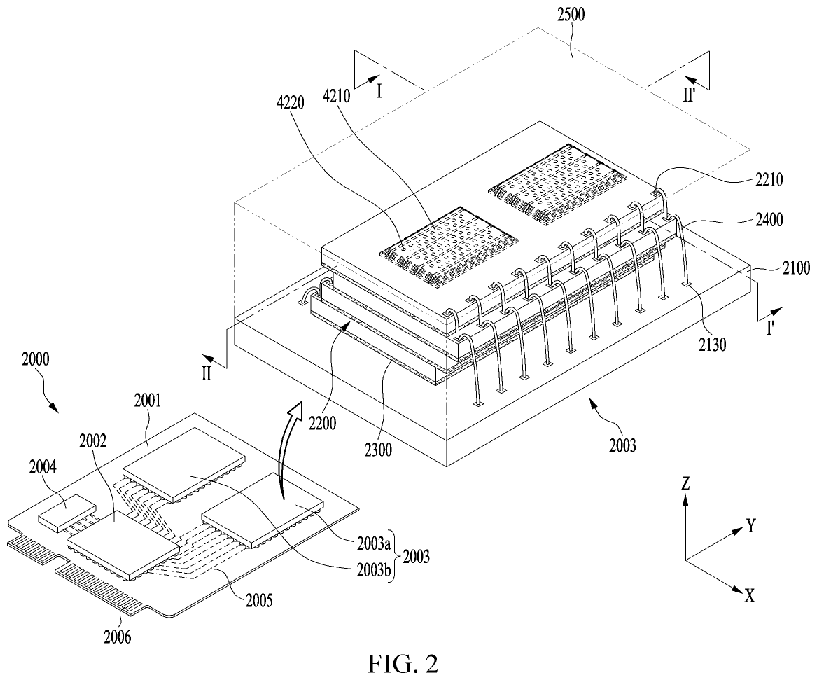

FIG. 2 is a perspective view schematically illustrating an electronic system including a semiconductor memory device according to an embodiment.

Referring to FIG. 2, an electronic system 2000 may include a main board 2001, a controller 2002 mounted on the main board 2001, one or more semiconductor packages 2003, and a dynamic random-access memory (DRAM) 2004. The semiconductor packages 2003 and the DRAM 2004 may be (electrically) connected to the controller 2002 through wiring patterns 2005 provided at the main board 2001.

The main board 2001 may include a connector 2006 including a plurality of pins that are (electrically) coupled to an external host. The number and arrangement of pins on the connector 2006 may vary based on a communication interface between the electronic system 2000 and the external host. The electronic system 2000 may communicate with the external host by any one of the interfaces, for example, USB, Peripheral Component Interconnect Express (PCI Express), Serial Advanced Technology Attachment (SATA), and M-PHY for Universal Flash Storage (UFS). The electronic system 2000 may include, for example, a power management integrated circuit (PMIC) that receives power from the external host through the connector 2006 and distributes the power to the controller 2002 and the semiconductor packages 2003.

The controller 2002 may write data to the semiconductor packages 2003, may read data from the semiconductor packages 2003, and may improve the operating speed of the electronic system 2000.

The DRAM 2004 may be a buffer memory to reduce the speed difference between the external host and the semiconductor packages 2003 that serve as data storage spaces. The DRAM 2004 included in the electronic system 2000 may operate as a kind of cache memory, and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

The semiconductor packages 2003 may include first and second semiconductor packages 2003a and 2003b that are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on lower surfaces (e.g., bottom surfaces) of the semiconductor chips 2200, connection structures 2400 for electrically connecting the semiconductor chips 2200 to the package substrate 2100, and a molding layer 2500 that lies on the package substrate 2100 and covers the semiconductor chips 2200 and the connection structures 2400.

The package substrate 2100 may be a printed circuit board (PCB) including package upper pads 2130. Each of the semiconductor chips 2200 may include input/output pads 2210. Each of the semiconductor chips 2200 may include stacked structures 4210 and channel structures 4220. Each of the semiconductor chips 2200 may include a semiconductor memory device described below.

The connection structures 2400 may be, for example, bonding wires electrically connecting the input/output pads 2210 to the package upper pads 2130. In each of the semiconductor packages 2003a and 2003b, the semiconductor chips 2200 may be electrically connected to each other in a bonding wire manner, and may be electrically connected to the package upper pads 2130 of the package substrate 2100. As another example, in each of the semiconductor packages 2003a and 2003b, the semiconductor chips 2200 may be electrically connected to each other by a through silicon via (TSV) instead of the bonding wire manner through the connection structures 2400.

Unlike the drawings, the controller 2002 and the semiconductor chips 2200 may be included in one package. The controller 2002 and the semiconductor chips 2200 may be mounted on a separate interposer substrate other than the main board 2001, and the controller 2002 and the semiconductor chips 2200 may be (electrically) connected to each other by wires provided on the interposer substrate.

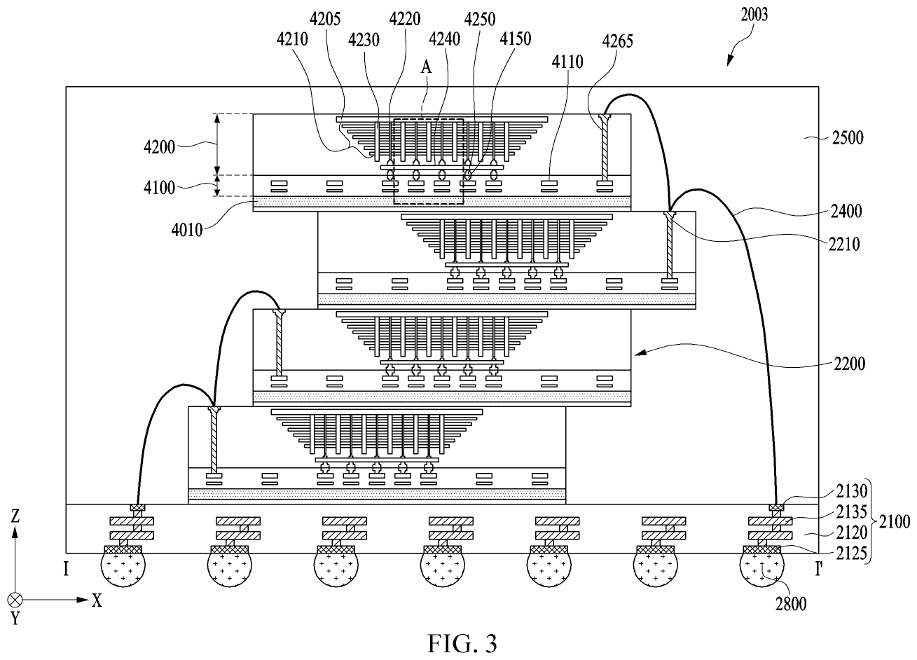

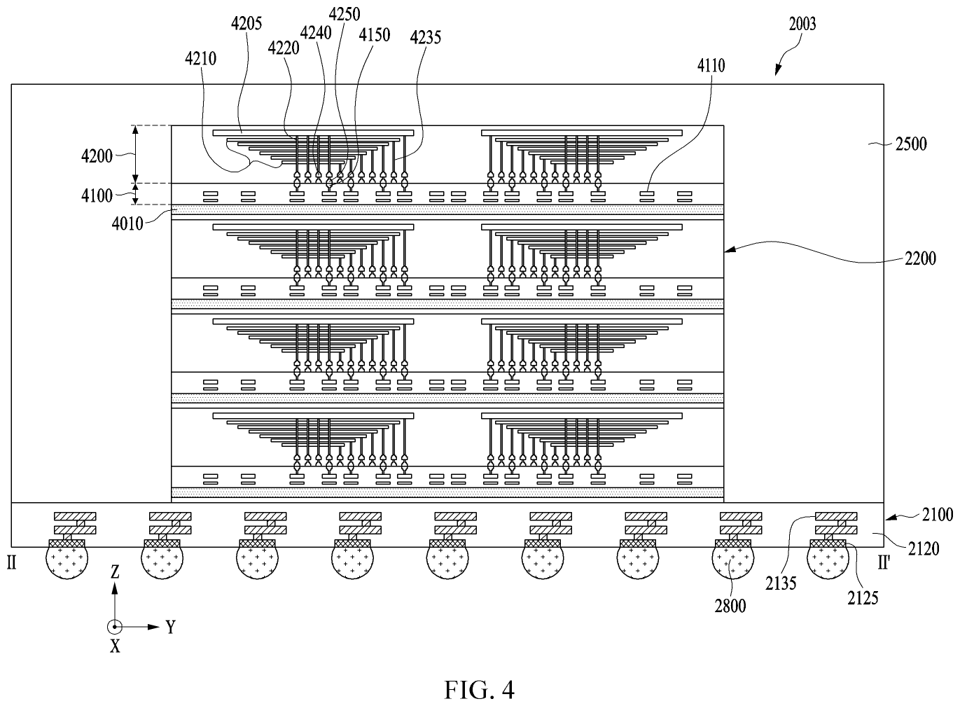

FIGS. 3 and 4 are cross-sectional views of a semiconductor package including a semiconductor memory device according to an embodiment, and correspond to cross-sections cut along a line I-I′ and a line II-II′ of FIG. 2, respectively.

Referring to FIGS. 3 and 4, the semiconductor package 2003 may include the package substrate 2100, the plurality of semiconductor chips 2200 on the package substrate 2100, and the molding layer 2500 covering the package substrate 2100 and the semiconductor chips 2200.

The package substrate 2100 may include a package substrate body 2120, package upper pads 2130 disposed on or exposed through a top surface of the package substrate body 2120, package lower pads 2125 disposed on or exposed through a lower surface (e.g., a bottom surface) of the package substrate body 2120, and internal wires 2135 electrically connecting the package upper pads 2130 to the package lower pads 2125 in the package substrate body 2120. The package upper pads 2130 may be electrically connected to the connection structures 2400. The package lower pads 2125 may be (electrically) connected through conductive connectors 2800 to wiring patterns 2005 of the main board 2001 of the electronic system 2000 shown in FIG. 2.

The plurality of semiconductor chips 2200 may be arranged such that each one of lateral walls thereof is unaligned with each other and the other lateral walls are aligned. The semiconductor chips 2200 may be electrically connected to each other by the connection structures 2400 in the form of bonding wires. Each of the semiconductor chips 2200 may include (substantially) the same components.

Each of the semiconductor chips 2200 may include a semiconductor substrate 4010, a first structure 4100 on the semiconductor substrate 4010, and a second structure 4200 on the first structure 4100. The second structure 4200 may be (electrically) coupled to the first structure 4100 in a wafer bonding manner.

The first structure 4100 may include peripheral circuit wires 4110 and first bonding pads 4150. The second structure 4200 may include a common source line 4205, a stacked structure 4210 between the common source line 4205 and the first structure 4100, channel structures 4220 and separation structures 4230 that extend in (e.g., penetrate) the stacked structure 4210, and second bonding pads 4250 respectively electrically connected to the channel structures 4220 and word lines (e.g., the word lines WL of FIG. 1) of the stacked structure 4210. For example, the second bonding pads 4250 may be electrically connected to the channel structures 4220 and the word lines (e.g., the word lines WL of FIG. 1) respectively, through bit lines 4240 electrically connected to the channel structures 4220 and through gate contact plugs 4235 electrically connected to the word lines (e.g., the word lines WL of FIG. 1). The first bonding pads 4150 of the first structure 4100 and the second bonding pads 4250 of the second structure 4200 may contact each other and may be (electrically) coupled to each other. A coupled portion of the first bonding pads 4150 and the second bonding pads 4250 may include, for example, copper (Cu).

Each of the semiconductor chips 2200 may further include the input/output pad 2210 and an input/output connection wire 4265 of a lower part of the input/output pad 2210. The input/output connection wire 4265 may be electrically connected to a portion of the second bonding pads 4250 and a portion of the peripheral circuit wires 4110.

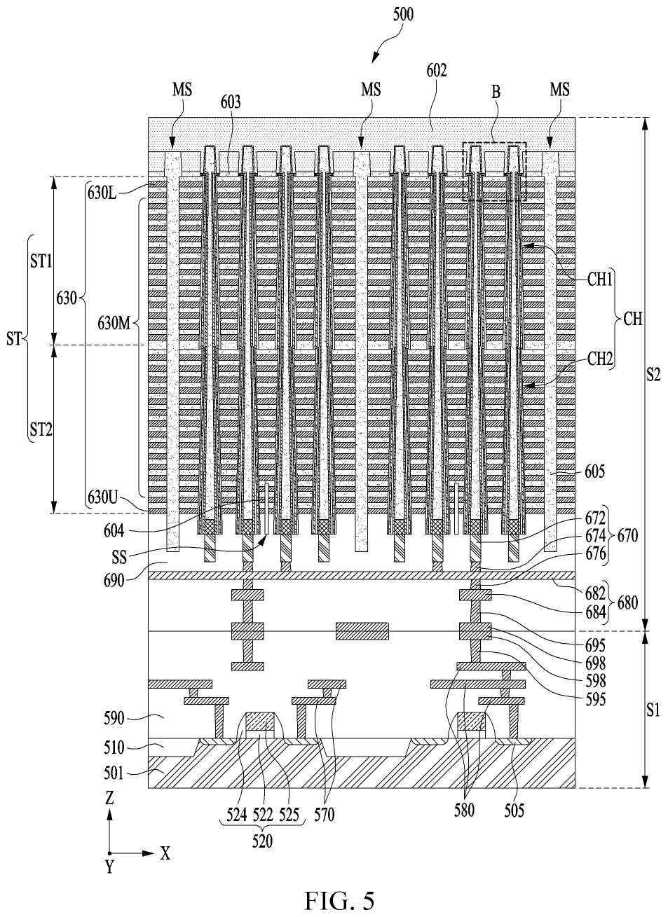

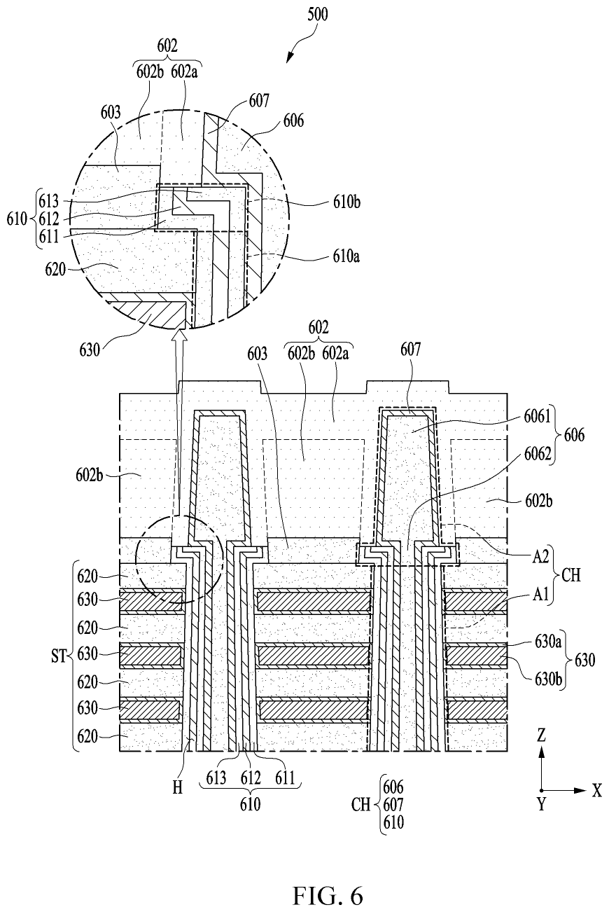

FIG. 5 is an example of a partial cross-sectional view of a semiconductor memory device, and corresponds to an area A of FIG. 3. FIG. 6 is an example of a partial cross-sectional view of a semiconductor memory device, and corresponds to an area B of FIG. 5.

In the shown embodiment, a vertical direction may be a direction (e.g., the Z axis) perpendicular to a main plane of a substrate (e.g., a substrate 501). A first horizontal direction may be a direction (e.g., the X axis) perpendicular to the vertical direction, and a second horizontal direction may be a direction (e.g., the Y axis) perpendicular to the vertical direction and the first horizontal direction. The horizontal direction may be an arbitrary straight-line direction disposed on a plane (e.g., the XY plane) perpendicular to the vertical direction. In a description of the embodiment, unless otherwise specified, it may be construed that an upper part of a specific component refers to the +Z axis direction, and a lower part refers to the −Z axis direction. Herein, a negative A direction and a positive A direction may be collectively referred to as A direction unless specified or clearly indicated by the contexts. For example, +Z axis direction and −Z axis direction may be collectively referred to as the Z direction (the vertical direction).

Referring to FIGS. 5 and 6, a semiconductor memory device 500 may include a first substrate structure S1 and a second substrate structure S2 that are stacked vertically. For example, the first substrate structure S1 (e.g., the first structure 4100 of FIG. 3) may include a peripheral circuit area of the semiconductor memory device 500, and the second substrate structure S2 (e.g., the second structure 4200 of FIG. 3) may include a memory cell area of the semiconductor memory device 500.

The first substrate structure S1 may include a substrate 501, source/drain areas 505 and element separation layers 510 in the substrate 501, circuit elements 520 disposed on/in the substrate 501, circuit contact plugs 570, circuit wiring lines 580, a peripheral area insulating layer 590, first bonding vias 595, and first bonding metal layers 598.

The substrate 501 may have an upper surface (e.g., a top surface) extending in the horizontal direction (e.g., the X-axis direction and the Y-axis direction). The element separation layers 510 may be formed on/in the substrate 501 to define an active area. The source/drain areas 505 including impurities may be disposed on/in a portion of the active area. The substrate 501 may include a semiconductor material, for example, a group IV semiconductor, a group III-V compound semiconductor, and/or a group II-IV compound semiconductor. For example, the substrate 501 may be provided as a single crystal bulk wafer.

The circuit elements 520 may include a planar transistor. Each of the circuit elements 520 may include a circuit gate dielectric layer 522, spacer layers 524, and a circuit gate electrode 525. The source/drain areas 505 may be disposed on/in the substrate 501 to be positioned on both sides (e.g., opposite sides) of the circuit gate electrode 525.

The peripheral area insulating layer 590 may be disposed on the circuit element 520 on the substrate 501. The circuit contact plugs 570 and the circuit wiring lines 580 may form a first wiring structure of the first substrate structure S1. For example, the circuit contact plugs 570 may be formed in a cylindrical pillar shape and may be (electrically) connected to the source/drain areas 505 by extending in (e.g., penetrating) the peripheral area insulating layer 590. An electrical signal may be applied to the circuit element 520 by the circuit contact plugs 570. In an area not shown in the drawings, the circuit contact plugs 570 may be (electrically) connected to the circuit gate electrode 525. The circuit wiring lines 580 may be (electrically) connected to the circuit contact plugs 570, may have a line shape, and may be arranged in a plurality of layers. It shall be noted that the number of layers of the circuit contact plugs 570 and the circuit wiring lines 580 may vary depending on the embodiment.

The first bonding vias 595 and the first bonding metal layers 598 may form a first bonding structure and may be disposed on a portion of the circuit wiring lines 580 disposed on an upper part (e.g., an uppermost part). The first bonding vias 595 may be formed in a cylindrical pillar shape and the first bonding metal layers 598 may have a line shape. The upper surfaces (e.g., the top surfaces) of the first bonding metal layers 598 may be exposed to the upper surface (e.g., the top surface) of the first substrate structure S1. The first bonding vias 595 and the first bonding metal layers 598 may function as a bonding structure or a bonding layer of the first substrate structure S1 and the second substrate structure S2. The first bonding vias 595 and the first bonding metal layers 598 may form an electrical connection path to the second substrate structure S2. Depending on the embodiment, a portion of the first bonding metal layers 598 may not be (electrically) connected to the lower circuit wiring lines 580 and may be disposed to provide only a bonding function. The first bonding vias 595 and the first bonding metal layers 598 may include a conductive material, for example, copper (Cu).

The peripheral area insulating layer 590 may include a bonding insulating layer disposed on the upper surface (e.g., the top surface) thereof. The bonding insulating layer may be a layer for bonding between dielectrics with a bonding insulating layer of the second substrate structure S2. The bonding insulating layer may function as a diffusion prevention layer of the first bonding metal layers 598. The bonding insulating layer may include, for example, SiO, SiN, SiCN, SiOC, SiON, and/or SiOCN.

The second substrate structure S2 may include a stacked structure ST including a plurality of gate electrodes 630 and interlayer insulating layers 620 that are alternately stacked in the vertical direction, a source structure 602 disposed on an upper part of the stacked structure ST, an intermediate insulating layer 603 positioned between the stacked structure ST and the source structure 602, a plurality of channel structures CH extending in (e.g., penetrating) the stacked structure ST in the vertical direction, and separation structures MS extending in (e.g., penetrating) the stacked structure ST in the vertical direction. The second substrate structure S2 may include insulating areas SS extending in (e.g., penetrating) a portion of the gate electrodes 630 and a cell area insulating layer 690 on (covering or overlapping) the gate electrodes 630. The second substrate structure S2 may include second bonding vias 695 and second bonding metal layers 698 that function as a second bonding structure. As used herein, “an element A overlapping an element B in a direction X” (or similar language) means that there is at least one line that extends in the direction X and intersects both the elements A and B.

The stacked structure ST may be formed by the plurality of gate electrodes 630 and the interlayer insulating layers 620 that are alternately stacked in the vertical direction. Each of the gate electrodes 630 may be separated by the interlayer insulating layer 620 disposed therebetween in the vertical direction. It shall be noted that the stacked structure ST may include a plurality of stacked structures ST1 and ST2 that are stacked in the vertical direction, but alternatively, may also be formed as a single stacked structure.

The gate electrodes 630 may include at least one ground selection gate electrode 630L forming a gate of a ground selection transistor, memory gate electrodes 630M forming a plurality of memory cells, and at least one string selection gate electrode 630U forming gates of string selection transistors. The number of memory gate electrodes 630M forming the memory cells may be determined depending on the capacity of the semiconductor memory device 500. Depending on the embodiment, the numbers of the string selection gate electrodes and the ground selection gate electrodes 630U and 630L may be one to four or more, respectively, and the string selection gate electrodes and the ground selection gate electrodes 630U and 630L may have the same or different structure from the memory gate electrodes 630M. The gate electrodes 630 may further include a gate electrode, which is disposed on a lower part of the ground selection gate electrode 630L and/or an upper part of the string selection gate electrode 630U and is used for an erasure operation using the GIDL phenomenon. Some of the gate electrodes 630, for example, the memory gate electrodes 630M adjacent to the ground selection gate electrode 630L or the string selection gate electrode 630U may be dummy gate electrodes. The gate electrodes 630 may be stacked to be spaced apart from each other in the vertical direction in the stacked structure ST, and may extend to different lengths in at least one direction to form a stepped shape step. Each of the gate electrodes 630 may include a first electrode layer 630a and a second electrode layer 630b. The first electrode layer 630a may be on (e.g., may cover or overlap) an upper surface (e.g., a top surface) and a lower surface (e.g., a bottom surface) of the second electrode layer 630b, and may be (e.g., may extend) between the channel structure CH and the second electrode layer 630b. The gate electrodes 630 may include a conductive material. For example, the first electrode layer 630a may include a high dielectric material, such as aluminum oxide (A1O), and the second electrode layer 630b may include, for example, titanium (Ti), titanium nitride (TiN), tantalum (Ta), tantalum nitride (TaN), tungsten (W), and/or tungsten nitride (WN). Depending on the embodiment, the gate electrodes 630 may include polycrystalline silicon or metal-semiconductor compound. A high dielectric material, herein, may refer to a material with a higher dielectric constant than that of silicon oxide.

The interlayer insulating layers 620 may be disposed between the (adjacent) gate electrodes 630. Similar to the gate electrodes 630, the interlayer insulating layers 620 may be spaced apart from each other in the vertical direction of the stacked structure ST, and may extend to different lengths in at least one direction to form a stepped shape step. The interlayer insulating layers 620 may include an insulating material, such as silicon oxide.

The source structure 602 may be disposed on the upper part of the stacked structure ST. The source structure 602 may have an upper surface (e.g., a top surface) extending in the horizontal direction (e.g., the X and Y axis directions). The source structure 602 may include a conductive material. For example, the source structure 602 may include, a semiconductor material, for example, a group IV semiconductor, a group III-V compound semiconductor, and/or a group II-IV compound semiconductor. For example, the group IV semiconductor may include silicon, germanium, and/or silicon-germanium. The source structure 602 may further include impurities. The source structure 602 may be provided as a polycrystalline semiconductor layer, such as a polycrystalline silicon layer. The source structure 602 may function as a portion of the common source line.

The semiconductor memory device 500 may further include a passivation layer (not shown) disposed on the upper surface (e.g., the top surface) of the source structure 602. The passivation layer may function as a protective layer for protecting the semiconductor memory device 500. In a portion of the passivation layer, a pad area in which an opening may be formed to (electrically) connect to an external device. The passivation layer may include, for example, silicon oxide, silicon nitride, and/or silicon carbide.

The intermediate insulating layer 603 may be disposed between the stacked structure ST and the source structure 602. The intermediate insulating layer 603 may be omitted at a position in which the channel structure CH is formed. For example, the intermediate insulating layer 603 may not overlap the channel structure CH in the vertical direction. The intermediate insulating layer 603 may include an insulating material. In an example, the intermediate insulating layer 603 may include a conductive material that is different from the interlayer insulating layers 620 of the stacked structure ST. For example, the intermediate insulating layer 603 may include silicon nitride, and the interlayer insulating layer 620 may include silicon oxide. However, the materials forming the intermediate insulating layer 603 and the interlayer insulating layer 620 are not limited thereto.

The channel structures CH may extend in (e.g., penetrate) the stacked structure ST and may (electrically) connect the source structure 602 to cell wiring lines 680, respectively. Each of the channel structures CH may be formed through a channel hole H extending in (e.g., penetrating) the stacked structure ST in the vertical direction. The channel structures CH may be disposed to be spaced apart from each other while forming rows and columns when viewing the stacked structure ST in the vertical direction (the Z-axis direction). For example, when viewing the stacked structure ST from the top, the plurality of channel structures CH may be arranged to form a lattice pattern or a zig-zag shape. The channel structures CH may have a pillar shape in the vertical direction and may be formed to have a shape of which the width decreases and is inclined as the channel structures CH approach to the source structure 602 according to the horizontal aspect ratio. Each of the channel structures CH may include a plurality of channel structures CH1 and CH2 that are stacked in the vertical direction. For example, when the stacked structure ST is formed as a shape in which the first stacked structure ST1 and the second stacked structure ST2 are stacked, each of the channel structures CH may be formed as a shape to which the first channel structure CH1 and the second channel structure CH2 are connected, wherein the first channel structure CH1 and the second channel structure CH2 extend in (e.g., penetrate) the first stacked structure ST1 and the second stacked structure ST2, respectively. It shall be noted that the number of channel structures CH1 and CH2 stacked in the vertical direction may vary depending on the embodiment.

The separation structures MS may extend in (e.g., penetrate) the stacked structure ST in the vertical direction and may be connected to the source structure 602. The separation structures MS may be disposed in parallel and may be spaced apart from each other in the first horizontal direction (the X-axis direction). The separation structures MS may extend in the second horizontal direction (the Y-axis direction) in the stacked structure ST and may extend in (e.g., penetrate) the gate electrodes 630. A separation insulating layer 605 may be formed in the separation structures MS. The separation insulating layer 605 may have a high aspect ratio and may be formed as a shape in which the width in the horizontal direction decreases toward the source structure 602, but the example is not limited thereto. In the separation structure MS, a conductive layer may be further formed in the separation insulating layer 605. The conductive layer may function as a common source line of the semiconductor memory device 500 or a contact plug connected to the common source line.

The insulating areas SS may extend in the second horizontal direction (the Y-axis direction) between the separation structures MS. The insulating areas SS may be formed to extend in (e.g., penetrate) a portion of the gate electrodes 630 including the string selection gate electrode 630U disposed in a lower part (e.g., a lowermost part) among the plurality of gate electrodes 630. For example, the insulating areas SS may separate a total of three gate electrodes 630 including the string selection gate electrode 630U from each other in the first horizontal direction (the X-axis direction). It shall be noted that the number of gate electrodes 630 separated by the insulating areas SS is an example and the number may vary depending on the embodiment. The string selection gate electrodes 630U separated by the insulating areas SS may form different string selection lines.

A second insulating layer 604 may be disposed in the insulating areas SS. The second insulating layer 604 may include an insulating material. For example, the second insulating layer 604 may include silicon oxide, silicon nitride, and/or silicon oxynitride.

Cell contact plugs 670 may include first, second, and third cell contact plugs 672, 674, and 676, and the cell wiring lines 680 may include first to second cell wiring lines 682 and 684. The first cell contact plugs 672 may be (electrically) connected to the second cell contact plugs 674 in the lower end and the second cell contact plugs 674 may be (electrically) connected to the first cell wiring lines 682 in the lower end. The third cell contact plugs 676 may (electrically) connect the first and second cell wiring lines 682 and 684 in the vertical direction. The cell contact plugs 670 may have a cylindrical shape. The cell contact plugs 670 may have different lengths. Depending on an aspect ratio, the cell contact plugs 670 may have an inclined side surface of which the width decreases as the inclined side surface approaches the source structure 602 and increases toward the first substrate structure S1. Depending on the embodiment, a portion of the cell contact plugs 670 may be a dummy contact plug to which an electrical signal is not applied.

The first cell wiring lines 682 may be disposed on the lower part of the stacked structure ST. The first cell wiring lines 682 may include bit lines (e.g., the bit line BL of FIG. 1) respectively (electrically) connected to the plurality of channel structures CH. The second cell wiring lines 684 may be wiring lines disposed lower than the first cell wiring lines 682. The cell wiring lines 680 may be formed as a line shape extending in at least one direction.

The cell contact plugs 670 and the cell wiring lines 680 may include, for example, tungsten (W), aluminum (Al), copper (Cu), tungsten nitride (WN), tantalum nitride (TaN), titanium nitride (TiN), and/or a combination thereof.

In an area not shown in the drawings, the second substrate structure S2 may further include through vias that extend in (e.g., penetrate) the source structure 602 and are (electrically) connected to the second wiring structure (e.g., the cell contact plugs 670, the cell wiring lines 680, the second bonding vias 695, and/or the second bonding metal layers 698) in the lower part.

The second bonding vias 695 of the second bonding structure may be disposed in the lower part of the second cell wiring lines 684 and may be (electrically) connected to the second cell wiring lines 684. The second bonding metal layers 698 of the second boding structure may be (electrically) connected to the second bonding vias 695. The lower surfaces (e.g., the bottom surfaces) of the second bonding metal layers 698 may be exposed to the lower surface (e.g., the bottom surface) of the second substrate structure S2. The second bonding metal layers 698 may be bonded and (electrically) connected to the first bonding metal layers 598 of the first substrate structure S1. The second bonding vias 695 and the second bonding metal layers 698 may include a conductive material, for example, copper (Cu).

The cell area insulating layer 690 may include a bonding insulating layer having a predetermined width from the bottom surface. In this case, the bonding insulating layer may form dielectric-dielectric bonding with the bonding insulating layer of the first substrate structure S1. For example, the bonding insulating layer may include, for example, SiO, SiN, SiCN, SiOC, SiON, and/or SiOCN.

The first and second substrate structures S1 and S2 may be bonded by bonding the first bonding metal layers 598 and the second bonding metal layers 698 and bonding the bonding insulating layers. The bonding of the first bonding metal layers 598 and the second bonding metal layers 698 may be, for example, copper (Cu)-copper (Cu) bonding, and the bonding of the bonding insulating layers may be, for example, dielectric-dielectric bonding, such as SiCN—SiCN bonding. The first and second substrate structures S1 and S2 may be bonded by hybrid bonding including copper (Cu)-copper (Cu) bonding and dielectric-dielectric bonding.

Referring to FIG. 6, in the semiconductor memory device 500, the source structure 602 may be disposed on the upper part of the stacked structure ST, and the intermediate insulating layer 603 may be disposed between the stacked structure ST and the source structure 602. Each of the channel stacked structures CH may extend in (e.g., penetrate) the stacked structure ST and the intermediate insulating layer 603, may extend to the upper part of the stacked structure ST, and may be (electrically) connected to the source structure 602 at the upper part of the stacked structure ST.

As shown in FIG. 6, each of the channel structures CH may include a first channel area A1 and a second channel area A2 divided based on a position in the vertical direction (the Z-axis direction) (and/or based on the shapes in a cross-sectional view).

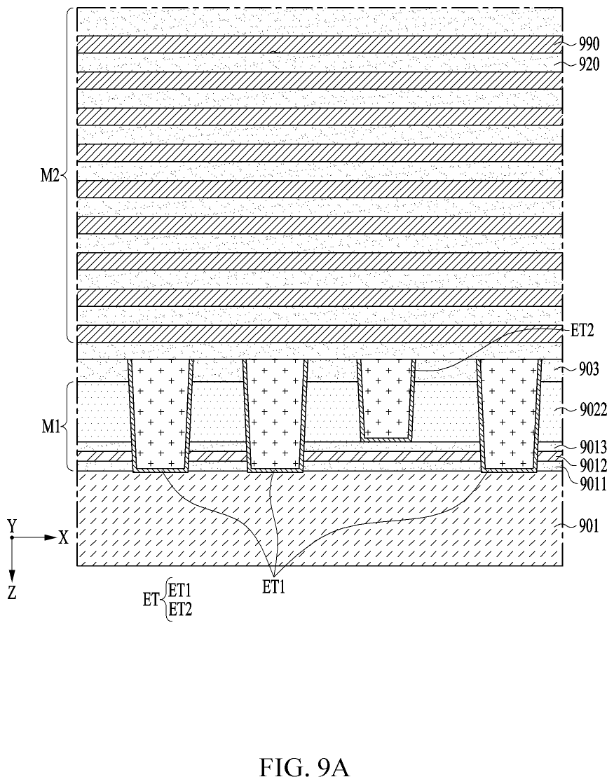

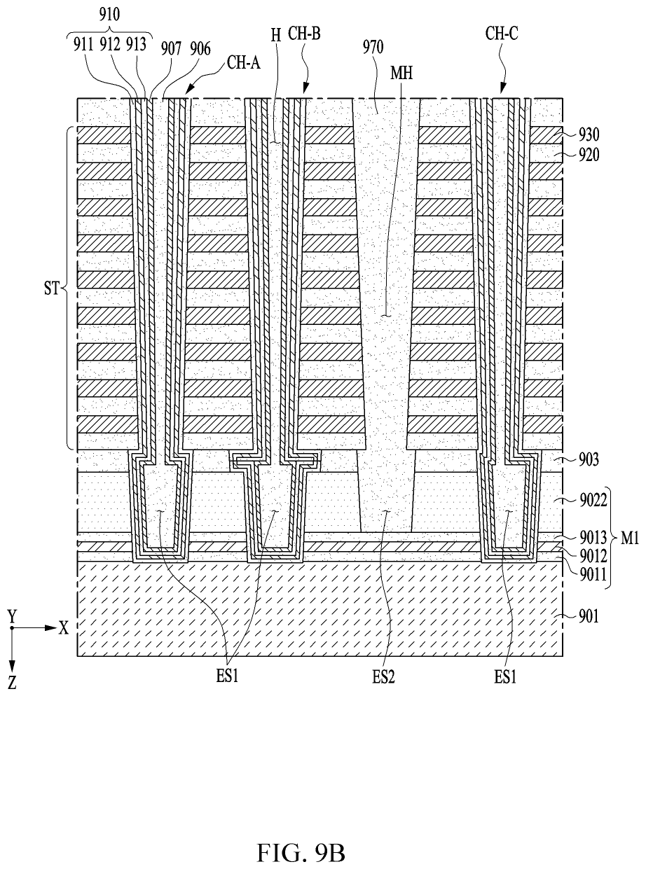

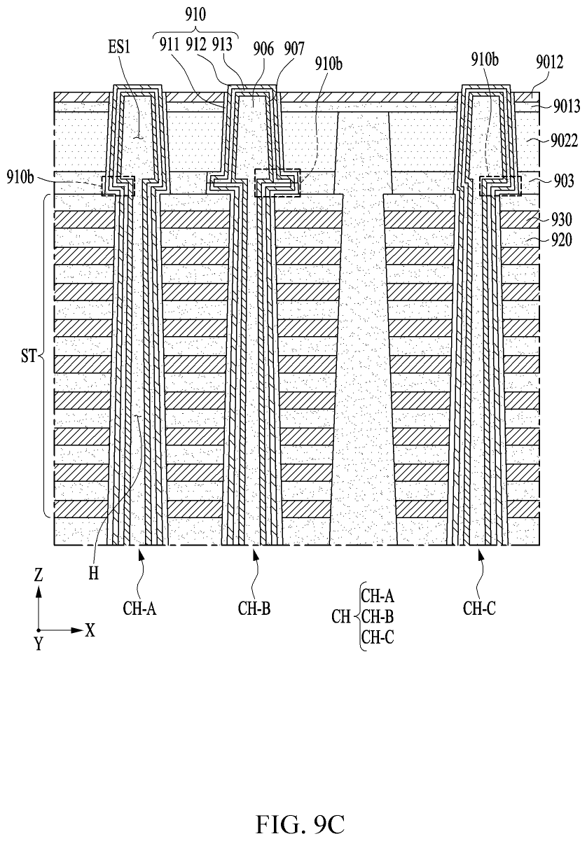

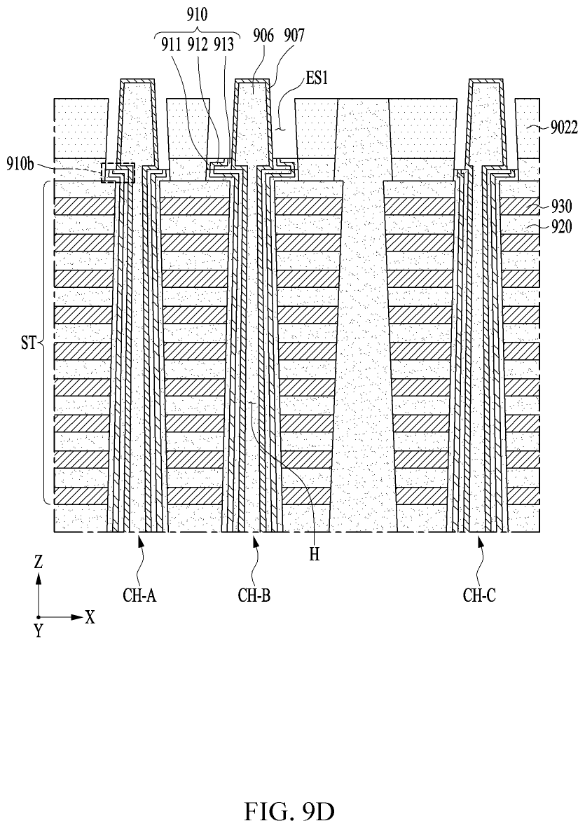

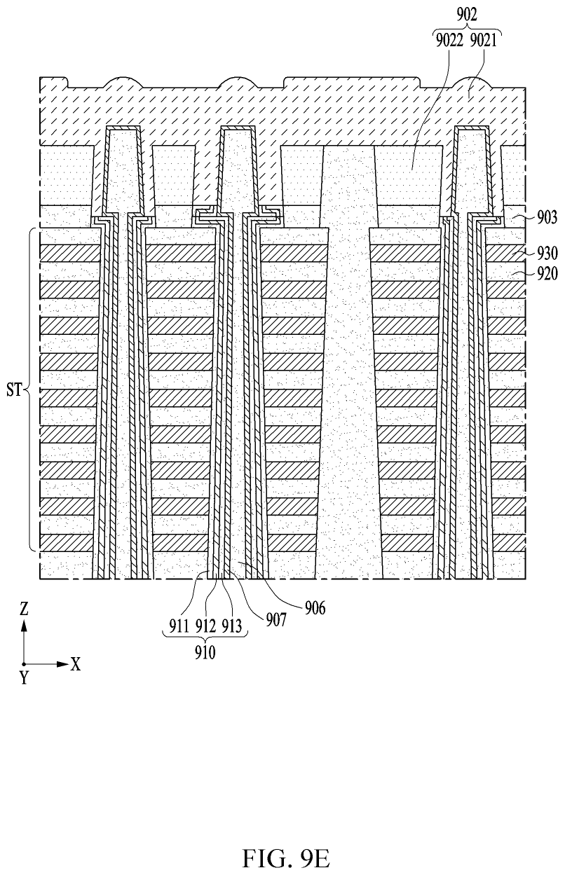

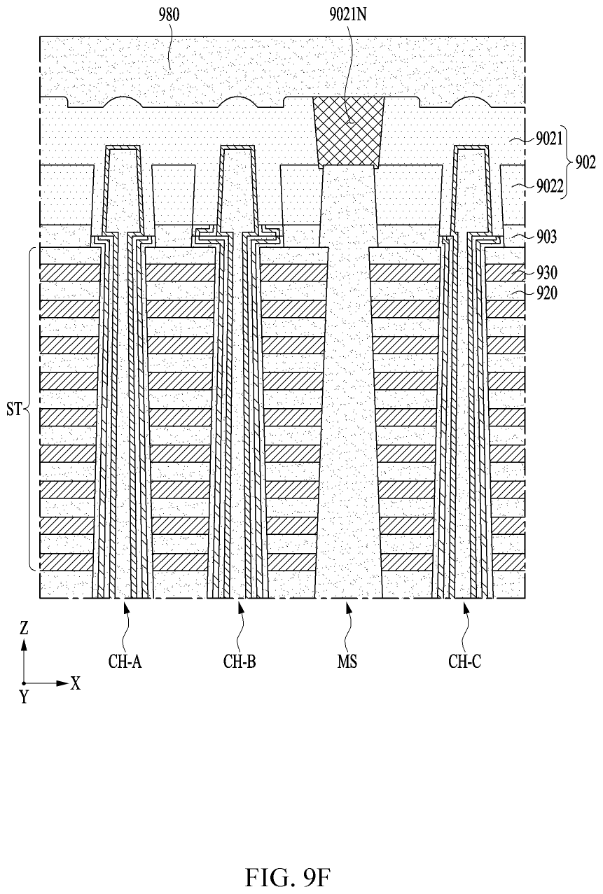

The first channel area A1 may be an area positioned in the stacked structure ST, for example, the channel hole H. The second channel area A2 may be an area positioned in the upper part of the stacked structure ST. For example, the second channel area A2 may be on the stacked structure ST. The channel structure CH may contact the source structure 602 in the second channel area A2. For example, the second channel area A2 may be in contact with the source structure 602. The first channel area A1 may be spaced apart from the source structure 602 by the second channel area A2. In each of the channel structures CH, the first channel area A1 may be an area formed by the channel hole H, and the second channel area A2 may be an area formed by an etch stopper (e.g., ET1 of FIG. 9A) installed to restrict an etching depth of the channel hole H. The etch stopper ET1 may be formed to have a greater width in the horizontal direction than the channel hole H, and thereby, the channel structure CH may be formed such that a lower end of the second channel area A2 is greater than an upper end of the first channel area A1 (in the horizontal direction).

The source structure 602 may include a first source part 602a and a plurality of second source parts 602b. The first source part 602a may include (e.g., may be formed of) a p-type doped polycrystalline silicon material. The second source part 602b may include (e.g., may be formed of) a p-type doped polycrystalline silicon material. At least a portion of the first source part 602a, for example, a part positioned on the upper part of a separation area (e.g., MS of FIG. 5) may be n-type doped. For example, a portion of the first source part 602a overlapped with the separation structure MS in the vertical direction may include an n-type doped material. The first source part 602a may contact the channel structure CH and may extend around (e.g., at least partially enclose) the second channel area A2 of the channel structure CH. For example, the first source part 602a may contact the side surface and the upper end of the second channel area A2. The plurality of second source parts 602b may extend around (e.g., at least partially enclose) the second channel area A2 of the plurality of channel structures CH with the first source part 602a interposed therebetween. For example, the second source part 602b may be spaced apart from the channel structure CH by the first source part 602a. The plurality of second source part 602b may be connected by the first source part 602a.

The second source part 602b may have a different crystal structure from the first source part 602a that extends around (at last partially encloses) the surroundings of the second source part 602b. The first source part 602a and the second source part 602b may be separately formed in different process steps during a process of manufacturing the semiconductor memory device 500 and may be connected to each other. For example, as described below, the second source part 602b may be formed by a sacrificial poly layer (e.g., 9022 of FIG. 9A) remaining after the etch stopper (e.g., ET1 of FIG. 9A) is formed, and the first source part 602a may be formed by polysilicon (e.g., 9021 of FIG. 9E) stacked to form a common source line after the channel structure CH is formed. For example, since the first source part 602a and the second source part 602b are formed in different process steps, the first source part 602a and the second source part 602b may have different crystal structures based on a final structure in which the process is completed, for example, the semiconductor memory device 500, due to differences in heat and crystallization time applied during the process. Accordingly, based on the final structure, an interface may be formed between the first source part 602a and the second source part 602b.

Based on the vertical direction, the upper surface (e.g., the top surface) of the channel structure CH facing an opposite direction to the stacked structure ST, for example, the upper surface (e.g., the top surface) of the second channel area A2, may be positioned higher than the upper surface (e.g., top surface) of the second source part 602b. This is because, as described below, during the process of forming the channel structure CH, an etch stopper (e.g., ET1 of FIG. 9A) that forms the second channel area A2 is formed on a sacrificial substrate (e.g., 901 of FIG. 9A) as the etch stopper extends in (e.g., penetrates) the sacrificial poly layer (e.g., 9022 of FIG. 9A). Each of the second source parts 602b may be formed to have a shape in which the width increases in the horizontal direction (e.g., the X-axis direction) as the second source part 602b moves away from the stacked structure ST (in the vertical direction). For example, the second source part 602b may have a reversed trapezoidal shape between the adjacent channel structures CH (e.g., between the adjacent second channel areas A2). A description thereof is provided later.

The intermediate insulating layer 603 may be disposed between at least a portion of the source structure 602 and the stacked structure ST. For example, the intermediate insulating layer 603 may be disposed between the second source part 602b and the stacked structure ST. Since the channel structure CH extends through (e.g., penetrates) the intermediate insulating layer 603 and extends to the inside the source structure 602, the intermediate insulating layer 603 may be omitted from the channel structure CH. The intermediate insulating layer 603 may overlap the gate electrode 630 when viewed in the vertical direction. For example, the intermediate insulating layer 603 may be disposed adjacent to a gate electrode (e.g., the ground selection gate electrode 630L of FIG. 5) disposed in an uppermost end of the plurality of gate electrodes 630. The intermediate insulating layer 603 may be disposed to extend around (at least partially enclose) the circumference of the channel stacked structure CH between the stacked structure ST and the second source part 602b.

Each of the channel structure CH may extend in the vertical direction while penetrating the stacked structure ST and the intermediate insulating layer 603, and may be (electrically) connected to the source structure 602 disposed on (the upper part of) the stacked structure ST. Each of the channel structure CH may include a core insulator 606, a channel layer 607, and a gate dielectric layer 610.

The core insulator 606 may extend in the vertical direction across the first channel area A1 and the second channel area A2. The core insulator 606 may extend along/in the channel hole H and may protrude toward the upper part of the stacked structure ST. The core insulator 606 may include a core extension part 6062 extending toward the upper part of the stacked structure ST in the vertical direction from the channel hole H and a core head part 6061 connected to an upper end of the core extension part 6062. The core extension part 6062 may extend from the first channel area A1 to the second channel area A2. The core head part 6061 may be formed in the second channel area A2. The lower part of the core head part 6061 may be formed to have a greater size (e.g., a greater width in the horizontal direction) than the upper end of the core extension part 6062 to form a step with the upper circumference of the core extension part 6062. The core insulator 606 may include silicon oxide or low-k dielectric material, but is not limited thereto.

The channel layer 607 may be on (e.g., may be formed to at least partially enclose) an outer surface of the core insulator 606. The channel layer 607 may extend around (e.g., at least partially enclose) the core insulator 606 in an annular shape. The channel layer 607 may enclose the entire outer surface of the core insulator 606 from the first channel area A1 to the second channel area A2. The channel layer 607 may be connected to the upper part of the stacked structure ST, for example, the source structure 602 in the second channel area A2. The channel layer 607 may function as a channel in which a carrier moves between a source and a drain. For example, the channel layer 607 may include a semiconductor material, such as polysilicon. In this case, the channel layer 607 may include undoped polysilicon. However, this is an example, and a material forming the channel layer 607 is not limited thereto.

The gate dielectric layer 610 may be on (e.g., at least partially enclose) a portion of the outer surface of the channel layer 607. For example, the gate dielectric layer 610 may extend in the vertical direction while extending around (e.g., at least partially enclosing) the outer surface of the channel layer 607 in the first channel area A1, for example, in the channel hole H. The gate dielectric layer 610 may extend from the first channel area A1 to at least a portion of the second channel area A2. For example, the gate dielectric layer 610 may be formed to a height that is lower than or the same as the top surface of the intermediate insulating layer 603. The gate dielectric layer 610 may be omitted from the upper part of the second channel area A2. For example, the gate dielectric layer 610 may be omitted such that the gate dielectric layer 610 is not on (does not enclose) the outer surface of the channel layer 607 at a position that is higher than the upper surface (e.g., the top surface) of the intermediate insulating layer 603 based on the vertical direction.

In the second channel area A2, the channel layer 607 of which the outer surface is exposed as the gate dielectric layer 610 is omitted may directly contact the first source part 602a of the source structure 602. The gate dielectric layer 610 may include a blocking layer 611, an information storage layer 612, and a tunneling layer 613. As the cross-section shown in FIG. 6, the blocking layer 611, the information storage layer 612, and the tunneling layer 613 may be sequentially stacked from the outside of the channel hole H to the inside. For example, the blocking layer 611 may be stacked on the outer surface of the information storage layer 612 in the channel hole H, and the tunneling layer 613 may be stacked between an internal surface of the information storage layer 612 and the channel layer 607. The blocking layer 611 may be a layer for insulating between the gate electrode 630 and the information storage layer 612. For example, the blocking layer 611 may include silicon oxide SiO, silicon oxynitride (SiON), a high-k dielectric material, and/or a combination thereof. The information storage layer 612 may be an electron trapping layer or a floating gate conductive layer. For example, the information storage layer 612 may include silicon nitride (SiN). The tunneling layer 613 may perform tunneling on an electron between the channel layer 607 and the information storage layer 612. For example, the tunneling layer 613 may include silicon oxide (SiO), silicon oxynitride (SiON), and/or a combination thereof.

The gate dielectric layer 610 may extend in (e.g., extend through) the channel hole H from the first channel area A1 and may extend in the horizontal direction from the second channel area A2 toward the outer circumference of the channel hole H. For example, the gate dielectric layer 610 may extend at a position between the upper end of the stacked structure ST and the core head part 6061 in the horizontal direction from the channel hole H toward the intermediate insulating layer 603. At least a portion of the gate dielectric layer 610 extending in the horizontal direction may contact the intermediate insulating layer 603 through an extended end. The end of the gate dielectric layer 610 extending in the horizontal direction may contact the intermediate insulating layer 603 and may be bent in the vertical direction toward the upper part of the second channel area A2. As the cross-section shown in FIG. 6, the gate dielectric layer 610 may include an extension part 610a extending from the channel hole H to the upper part of the stacked structure ST in the vertical direction, and a first horizontal part 610b connected to an upper end of the extension part 610a and extending toward the outside of the core insulator 606 in the horizontal direction. The first horizontal part 610b may be bent in the second channel area A2 and may extend in the horizontal direction toward the intermediate insulating layer 603. When viewing the upper end of the stacked structure ST in the vertical direction, at least a portion of the first horizontal part 610b may overlap the gate electrode 630 (in the vertical direction). The cross-section of FIG. 6 illustrates that the first horizontal part 610b of the gate dielectric layer 610 extends in the first horizontal direction (+/−X direction). However, it shall be noted that indeed, the first horizontal part 610b of the gate dielectric layer 610 may extend in parallel with the upper surface (e.g., the top surface) of the stacked structure ST toward the outer circumference of the core insulator 606, in other words, may extend radially on the XY plane.

The gate dielectric layer 610 may contact the source structure 602 (e.g., the first source part 602a) at a height that is lower than or the same as the upper surface (e.g., the top surface) of the intermediate insulating layer 603. For example, the gate dielectric layer 610 may be omitted from the second channel area A2 part at a position that is higher than (the upper surface of) the intermediate insulating layer 603, for example, on the upper part of the intermediate insulating layer 603.

Based on one channel structure CH, the extension part 610a of the gate dielectric layer 610 may extend in the vertical direction while extending around (e.g., at least partially enclosing) the circumference of the core extension part 6062. The upper end of the extension part 610a, for example, an upper end of an extension part 610a to which the first horizontal part 610b is connected may be positioned on the same plane perpendicular to the vertical direction. For example, in the cross-section view shown in FIG. 6, based on one channel structure CH, an upper end of an extension part 610a positioned in the −X direction of the core extension part 6062 and the upper end of the extension part 610a positioned in the +X direction may be positioned at the same height based on the vertical direction (may be coplanar with each other). In the plurality of channel structures CH formed in one stacked structure ST, upper ends of extension parts 610a may be positioned at the same height based on the vertical direction. In one channel structure CH, lengths extending in the horizontal direction of the first horizontal part 610b may be different from each other depending on the direction. For example, when viewed in the vertical direction, the length from the center of the channel hole H to an edge of the first horizontal part 610b (in the horizontal direction) may vary depending on the position. For example, in the cross-section view shown in FIG. 6, the length of the first horizontal part 610b extending in the −X direction relative to the core extension part 6062 may be different from the length of the first horizontal part 610b extending in the +X direction. Alternatively, the first horizontal part 610b may extend from the center of the channel hole H in the horizontal direction at the same length (a uniform length) and may form a (substantially) circular shape.

In the process of forming the channel structure CH, the gate dielectric layer 610 may be sequentially removed from the upper part of the channel structure CH (in other words, in the −Z direction) in the vertical direction through a butting process. For example, the first horizontal part 610b of the gate dielectric layer 610 may be preferentially removed compared to the extension part 610a. While removing the gate dielectric layer 610, a removal degree of the gate dielectric layer 610 may vary depending on the position. Since the first horizontal part 610b of the gate dielectric layer 610 may be preferentially removed compared to the extension part 610a, the first horizontal part 610b may perform a buffer function to maintain the vertical length for each part of the gate dielectric layer 610 or minimize a deviation while being removed. Since the vertical length of the gate dielectric layer 610 affects a drain saturation current (Idsat) according to a gate voltage, the vertical length of each part of the gate dielectric layer 610 may be uniformly maintained while the first horizontal part 610b is removed. Accordingly, the performance degradation of the drain saturation current of the channel structure CH may be mitigated or prevented through the first horizontal part 610b. Furthermore, when a butting process is performed on the plurality of channel structures CH formed on the stacked structure ST for the same duration, since the vertical length of the gate dielectric layer 610 of each channel structure CH is constant or a deviation of vertical lengths is maintained within a predetermined range while the first horizontal part 610b is removed, a difference in the performance of the drain saturation current of the plurality of channel structures CH may be minimized or mitigated.

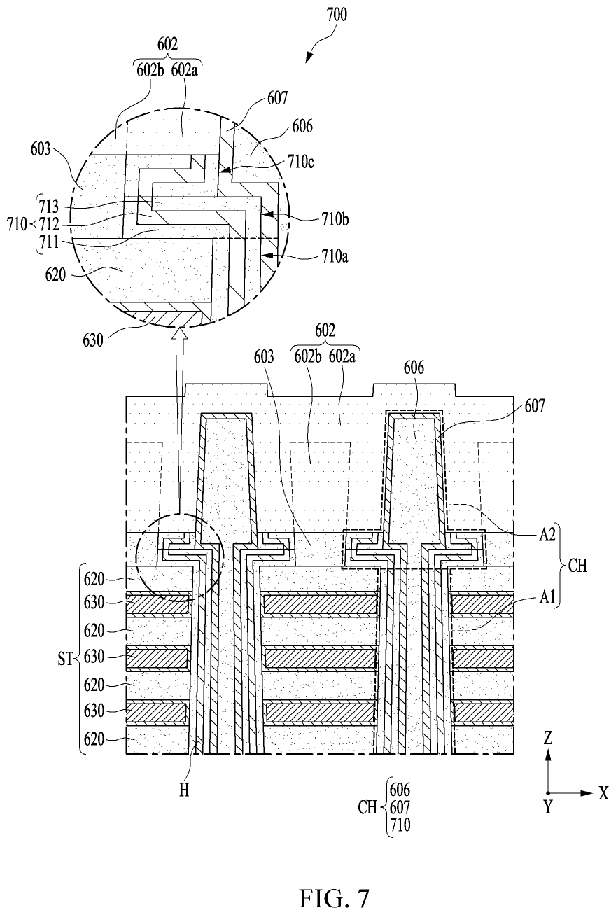

FIG. 7 is an example of a partial cross-sectional view of a semiconductor memory device and corresponds to an area B of FIG. 5.

Referring to FIG. 7, in a semiconductor memory device 700, the channel structure CH may extend in (e.g., penetrate) the stacked structure ST and the intermediate insulating layer 603 in the vertical direction and may be (electrically) connected to the source structure 602 at the upper part of the stacked structure ST. Each of the channel structure CH may include the core insulator 606, the channel layer 607 extending around (e.g., at least partially enclosing) the outer surface of the core insulator 606, and a gate dielectric layer 710 extending around (e.g., at least partially enclosing) a portion of the channel layer 607. The stacked structure ST may include the plurality of gate electrodes 630 and the interlayer insulating layers 620 that are alternately stacked in the vertical direction.

The core insulator 606 may extend from the first channel area A1 in the stacked structure ST to the second channel area A2 in the upper part of the stacked structure ST. The channel layer 607 may be on (e.g., may extend around or at least partially enclose) the outer surface of the core insulator 606 and may be (electrically) connected to the source structure 602 in the second channel area A2. The source structure 602 may include a first source part 602a and a plurality of second source parts 602b.

The gate dielectric layer 710 may extend in the vertical direction while extending around (e.g., at least partially enclosing) the outer surface of the channel layer 607 in the first channel area A1 and may extend in the horizontal direction along the outer circumference of the channel hole H toward the intermediate insulating layer 603 in the second channel area A2. An end of the gate dielectric layer 710 extending in the horizontal direction may contact the intermediate insulating layer 603 and may be bent toward the upper part of the channel area A2.

The gate dielectric layer 710 may extend to a position that is the same as or lower than (the upper surface of) the intermediate insulating layer 603 based on the vertical direction. The gate dielectric layer 710 may be omitted from the outer surface of the channel layer 607 in at least the upper part of the second channel area A2. Based on the vertical direction, the upper part of the second channel area A2 may refer to a higher position than the upper surface (e.g., the top surface) of the intermediate insulating layer 603. As the gate dielectric layer 710 is omitted from the higher position than (the upper surface of) the intermediate insulating layer 603, a portion of the channel layer 607 may be exposed. The gate dielectric layer 710 may include a blocking layer 711, an information storage layer 712, and a tunneling layer 713.

The gate dielectric layer 710 may include an extension part 710a extending in the vertical direction from the first channel area A1 along/in the channel hole H, a first horizontal part 710b connected to an upper end of the extension part 710a and extending in the horizontal direction from the channel hole H to the intermediate insulating layer 603 in the second channel layer A2, and a second horizontal part 710c connected to an extended end of the first horizontal part 710b and extending from an upper part of the first horizontal part 710b to the core insulator 606. Based on the vertical direction, the first horizontal part 710b and the second horizontal part 710c may be positioned between the upper surface (e.g., the top surface) of the stacked structure ST and the upper surface (e.g., the top surface) of the intermediate insulating layer 603. In some embodiments, the gate dielectric layer 710 may further include a vertically extending portion that is connected to the second horizontal part 710c. The vertically extending portion may be on the second horizontal part 710c and in contact with the channel layer 607. For example, the vertically extending portion may extend from the second horizontal part 710c toward the source structures 602. Herein, the extension part 710a, the first horizontal part 710b, and the second horizontal part 710c may form a unitary structure. A unitary structure (e.g., the channel structure CH) herein may refer to a structure (e.g., a continuum) without a (visible) boundary between its sub-structures.

When viewed in the vertical direction, the second horizontal part 710c may overlap the first horizontal part 710b (in the vertical direction). The second horizontal part 710c may extend from an extended edge of the first horizontal part 710b, for example, from the intermediate insulating layer 603 to (toward) the center of the channel hole H. The second horizontal part 710c may have a smaller area compared to the first horizontal part 710b. Based on the cross-section of FIG. 7, the upper surface (e.g., the top surface) of the first horizontal part 710b and the lower surface (e.g., the bottom surface) of the second horizontal part 710c may face each other. The tunneling layer 713 of the first horizontal part 710b and the tunneling layer 713 of the second horizontal part 710c may be connected to contact each other. As another example, the channel layer 607 may be positioned between the tunneling layer 713 of the first horizontal part 710b and the tunneling layer 713 of the second horizontal part 710c.

In a butting process for removing the gate dielectric layer 710, the first horizontal part 710b may be removed from the gate dielectric layer 710 after the second horizontal part 710c is removed. In the butting process, depending on the etching degree of each part of the gate dielectric layer 710, only a portion of the second horizontal part 710c may be removed from a specific part of the gate dielectric layer 710, whereas in another part, the second horizontal part 710c may be completely removed and a portion of the first horizontal part 710b may be removed. The gate dielectric layer 710 may minimize a length discrepancy of each part in the vertical direction of the gate dielectric layer 710 depending on the etching degree of each part through the first horizontal part 710b and the second horizontal part 710c. Accordingly, in the first channel structure CH, the performance degradation of the drain saturation current of the channel structure CH may be minimized or mitigated by maintaining the vertical length of the gate dielectric layer 710 constant or minimizing a deviation. Furthermore, the performance degradation of each drain saturation current of the plurality of channel structures CH formed on one stacked structure ST may be minimized or mitigated.

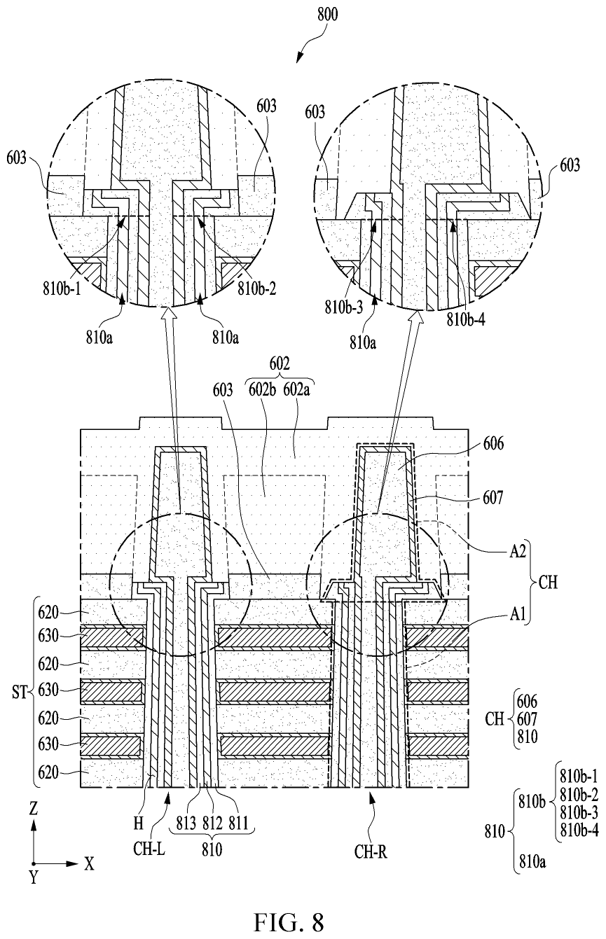

FIG. 8 is an example of a partial cross-sectional view of a semiconductor memory device, and corresponds to an area B of FIG. 5.

Referring to FIG. 7, in a semiconductor memory device 800, the channel structure CH may extend in (e.g., penetrate) the stacked structure ST and the intermediate insulating layer 603 in the vertical direction and may be connected to the source structure 602 at the upper part of the stacked structure ST. The stacked structure ST may include the plurality of gate electrodes 630 and the interlayer insulating layers 620 that are alternately stacked in the vertical direction. The source structure 602 may include a first source part 602a and a plurality of second source parts 602b.

Each of the channel structure CH may include the core insulator 606, the channel layer 607 on (e.g., extending around or at least partially enclosing) the outer surface of the core insulator 606, and a gate dielectric layer 810 on (e.g., extending around or at least partially enclosing) a portion of the channel layer 607. The core insulator 606 may extend from the first channel area A1 in the stacked structure ST to the second channel area A2 in the upper part of the stacked structure ST. The channel layer 607 may extend around (e.g., at least partially enclose) the outer surface of the core insulator 606 and may be (electrically) connected to the source structure 602 in the second channel area A2. The gate dielectric layer 810 may include a blocking layer 811, an information storage layer 812, and a tunneling layer 813 that are sequentially stacked (on the stacked structure ST).

The gate dielectric layer 810 may include an extension part 810a extending around (e.g., at least partially enclosing) the outer surface of the channel layer 607 in the first channel area A1 and extending in the vertical direction, and a first horizontal part 810b connected to the extension part 810a and extending in the horizontal direction along the outer circumference of the channel hole H in the second channel area A2. The first horizontal part 810b of the gate dielectric layer 810 may extend in the horizontal direction from the channel hole H to (toward) the intermediate insulating layer 603. After at least a portion of an end of the first horizontal part 810b contacts the intermediate insulating layer 603, the portion of the end of the first horizontal part 810b may be bent and extend toward the upper part of the channel area A2. The gate dielectric layer 810 may be omitted from the upper part of the second channel area A2, for example, at a position that is higher than (the upper surface of) the intermediate insulating layer 603.

At least one channel structure CH-R of a plurality of channel structures CH-L and CH-R formed in the stacked structure ST may have an asymmetric shape in the horizontal direction. For example, in the two channel structures CH-L and CH-R shown in FIG. 8 as an example, the left channel structure CH-L may be formed in which first horizontal (e.g., the X-axis) centers of the first channel area A1 and the second channel area A2 are aligned, whereas the right channel structure CH-R may be formed in which the first horizontal center of the second channel area A2 is offset in the +X direction and is unaligned (misaligned) relative to the first horizontal center of the first channel area A1. When forming the channel hole H, a symmetrical channel structure, such as the left channel structure CH-L, may be formed when the horizontal center of the channel hole H is aligned to the horizontal center of an etch stopper (e.g., ET1 of FIG. 9A). While forming the channel hole H, an asymmetrical channel structure, such as the right channel structure CH-R, may be formed when the horizontal center of the channel hole His unaligned (misaligned) relative to the horizontal center of the etch stopper (e.g., ET1 of FIG. 9A).

While only a portion of an upper end of the first horizontal part 810b is removed, in the symmetrical channel structure, for example, the left channel structure CH-L, the length of a first-first horizontal part 810b-1 extending in the −X direction from the extension part 810a may be (substantially) the same as the length of a first-second horizontal part 810b-2 extending in the +X direction from the extension part 810a. While only a portion of the upper end of the first horizontal part 810b is removed, in the asymmetrical channel structure, for example, the right channel structure CH-R, the length of a first-third horizontal part 810b-3 extending in the −X direction from the extension part 810a may be less than the length of a first-fourth horizontal part 810b-4 extending in the +X direction from the extension part 810a. In a butting process, since the first horizontal part 810b of each of the channel structures CH is removed before the extension part 810a and is able to function as a buffer for reducing the vertical length discrepancy of the gate dielectric layer 810, even if a portion of the channel structure CH-R is formed as a shape in which the centers of the first channel area A1 and the second channel area A2 are unaligned (misaligned) in the horizontal direction, the vertical length of the gate dielectric layer 810 of each of the plurality of channel structures CH formed in the stacked structure ST may be maintained constant or may have a minimized discrepancy. Accordingly, the performance degradation of the drain saturation current of the channel structure CH may be minimized or mitigated.

In some examples, as a portion of the first horizontal part 810b is removed from at least one channel structure (e.g., the right channel structure CH-R), a portion of the upper end of the extension part 810a may be removed. For example, in the case of the right channel structure CH-R, the first-third horizontal part 810b-3 may be removed before the first-fourth horizontal part 810b-4, a portion of the upper end of the extension part 810a connected to the first-third horizontal part 810b-3 may be removed, and thereby, the extension part 810a connected to the first-third horizontal part 810b-3 may have a vertical length that is shorter than the extension part 810a connected to the first-fourth horizontal part 810b-4. In this case, since the length of the extension part 810a is maintained constant at least while the first-third horizontal part 810b-3 is removed, a degree of an occurrence of vertical length discrepancy for each part of the gate dielectric layer 810 may decrease compared to a case in which the first horizontal part 810b is not formed.

FIGS. 9A, 9B, 9C, 9D, 9E, and 9F are schematic cross-sectional views illustrating a semiconductor memory device according to an embodiment.

In FIGS. 9A. 9B, 9C, 9D, 9E, and 9F, three different channel structures CH-A, CH-B, and CH-C are illustrated to help description. For example, a channel structure A CH-A may correspond to the channel structure shown in FIG. 6, a channel structure B CH-B may correspond to the channel structure shown in FIG. 7, and a channel structure C CH-C may correspond to the channel structure shown in FIG. 8 (CH-R of FIG. 8). However, the shape, arrangement, and number of channel structures formed in a semiconductor memory device are not limited thereto, and it shall be noted that the shape of the shown channel structure is only for convenience of description.

Referring to FIG. 9A, a sacrificial substrate 901 may be provided, and a first mold structure M1 may be stacked on the sacrificial substrate 901. The first mold structure M1 may include a first sacrificial layer 9011, a second sacrificial layer 9012, a third sacrificial layer 9013, a sacrificial poly layer 9022, and an intermediate insulating layer 903 that are sequentially stacked in the −Z direction. For example, the first sacrificial layer 9011 and the third sacrificial layer 9013 may include silicon oxide SiO. The second sacrificial layer 9012 may include silicon nitride (SiN) or silicon oxynitride (SiON). The sacrificial poly layer 9022 may include p-type doped polysilicon.

Thereafter, a portion of the first mold structure M1 may be removed through an etching process, and a plurality of etch stoppers ET may be formed by filling a removed space with a metal material (e.g., tin nitride and/or tungsten). The etch stopper ET may be a structure for limiting the etch depth in a subsequent process. The plurality of etch stoppers ET may include a first etch stopper ET1 for limiting the etch depth of a channel hole (H of FIG. 9B) in which a channel structure is formed, and a second etch stopper ET2 for limiting the etch depth of a separation hole (MH of FIG. 9B) in which a separation structure is formed. The first etch stopper ET1 may extend in (e.g., penetrate) the first mold structure M1 and may be formed up to the inside or the upper surface (e.g., the top surface) of the sacrificial substrate 901, and the second etch stopper ET2 may extend in (e.g., penetrate) the sacrificial poly layer 9022 and may be formed to the upper surface (e.g., the top surface) of the third sacrificial layer 9013. After the metal material is filled, the metal material remaining on the upper end of the intermediate insulating layer 903 may be removed through a chemical mechanical polishing (CMP) process. Hereinafter, for ease of description, a space formed by the first etch stopper ET1 is referred to as a first etch stopper space (ES1 of FIG. 9B), and a space formed by the second etch stopper ET2 is referred to as a second etch stopper space (ES2 of FIG. 9B).

Thereafter, a second mold structure M2 may be stacked on the intermediate insulating layer 903 in the −Z direction. The second mold structure M2 may include an interlayer insulating layer 920 and a sacrificial insulating layer 990 that are alternately stacked. The interlayer insulating layer 920 and the sacrificial insulating layer 990 may be stacked as a plurality of layers, respectively. The second mold structure M2 may be a portion corresponding to the upper stacked structure ST1 of FIG. 5. The sacrificial insulating layer 990 may be substituted with the gate electrode 630 of FIG. 5 through a subsequent process.

Referring to FIGS. 9A and 9B, after the second mold structure M2 is stacked, a channel hole H and a separation hole MH may be formed in the second mold structure M2 through an etching process. For example, after the second mold structure M2 is stacked, the channel hole H and the separation hole MH may be formed up to the upper ends of the first etch stopper ET1 and the second etch stopper ET2 in the +Z direction, respectively. During the etching process for forming the channel hole H and the separation hole MH, the etch stopper ET may not be etched according to a selectivity ratio. For example, the second mold structure M2 may be etched up to the upper end of the etch stopper in the −Z direction as the etch stopper ET limits the etch depth of the second mold structure M2 in the +Z direction. The channel hole H may be formed as a shape in which the width narrows toward the first etch stopper ET1. In a position in which the first etch stopper ET1 and the channel hole H are in contact with each other, the horizontal width (e.g., the X-axis width) of the channel hole H may be less than the horizontal width of the first etch stopper ET1. While forming each channel hole H, it may be preferable to align the horizontal center of the channel hole H with the horizontal center of the first etch stopper ET1. However, in some cases, the horizontal center of the channel hole H may be unaligned (misaligned) with the center of the etch stopper ET1 as the channel structure C CH-C. It shall be noted that the shape of the channel structure C CH-C shown in FIGS. 9A, 9B, 9C, 9D, 9E, and 9F is illustrated as an example for ease of description.

Thereafter, the first etch stopper ET1 and the second etch stopper ET2 may be removed through an etching process (e.g., a wet etching process) and may be connected to (integrated with) the channel hole H and the separation hole MH, respectively. Thereafter, the first etch stopper space ES1 and the channel hole H may be filled with a sacrificial material, an additional mold structure may be stacked on the upper part (e.g., the −Z direction) of the second mold structure (e.g., M2), and a second stacked structure (e.g., ST2 of FIG. 5) may be formed by forming a channel hole and a separation hole in the additional mold structure.

Thereafter, the sacrificial material may be removed from the channel hole H and the first etch stopper space ES1, the gate dielectric layer 910, a channel layer 907, and a core insulator 906 are sequentially stacked on the outer surfaces of the channel hole H and the first etch stopper space ES1, and the channel structures CH-A, CH-B, and CH-C may be formed. The gate dielectric layer 910 may include a blocking layer 911, an information storage layer 912, and a tunneling layer 913 that are sequentially stacked on the outer surfaces of the channel hole H and the first etch stopper space ES1. In the channel hole H, a first channel area (e.g., the first channel area A1 of FIG. 6) of the channel structure may be formed. In the first etch stopper space ES1, a second channel area (e.g., the second channel area A2 of FIG. 6) of the channel structure may be formed. Since the width of the first etch stopper space ES1 extends in the horizontal direction at a position in contact with the channel hole H, the gate dielectric layer 910 stacked on the first etch stopper space ES1 may be stacked as a shape that extends in the horizontal direction along the circumference of the channel hole H. A part of the gate dielectric layer 910 stacked on the outer surface of the channel hole H may extend in the vertical direction along the channel hole H, and a part of the gate dielectric layer 910 extending in the horizontal direction in the first etch stopper space ES1 along the circumference of the channel hole H may form a horizontal part (910b of FIG. 9C) in contact with the intermediate insulating layer 903.

The sacrificial insulating layer 990 of FIG. 9A may be substituted with a conductive material and may form a gate electrode 930. A separation insulating layer 970 may be stacked on (may be formed in) the separation hole MH and the second etch stopper space ES2.

In FIG. 9B, while forming the channel structure B CH-B, the first etch stopper space ES1 may expand in the horizontal direction to (toward) the intermediate insulating layer 903 between the stacked structure ST and the sacrificial poly layer 9022. The gate dielectric layer 910 stacked on the first etch stopper space ES1 of the channel structure B CH-B may be formed as a shape that extends in the horizontal direction from the channel hole H toward the intermediate insulating layer 903 along the upper surface (e.g., the top surface) of the stacked structure ST, and then extends from the intermediate insulating layer 903 toward the channel hole H, and thereby, may form the shape in which a horizontally extended part is stacked in the vertical direction, for example, the shapes of the first horizontal part 710b and the second horizontal part 710c shown in FIG. 7.

Thereafter, a second substrate structure (e.g., S2 of FIG. 5) may be formed by forming a cell wiring line (e.g., 682 of FIG. 5) including a bit line and cell contact plugs (e.g., 670 of FIG. 5) on the upper part (e.g., the −Z direction) of the formed stacked structure ST, and the second substrate structure S2 may be flipped to be bonded to a first substrate structure (e.g., S1 of FIG. 5) including a peripheral circuit area.

Referring to FIGS. 9C and 9D, a sacrificial substrate (901 of FIG. 9B) may be removed from the flipped stacked structure ST through grinding, CMP, and/or etching processes. After the sacrificial substrate is removed, the first sacrificial layer 9011, the second sacrificial layer 9012, and the third sacrificial layer 9013 may be sequentially removed through a butting process. While removing the first sacrificial layer 9011, the second sacrificial layer 9012, and the third sacrificial layer 9013, the gate dielectric layer 910 may be (at least partially) removed from the upper end and the channel layer 907 may be exposed. For example, while removing the first sacrificial layer 9011, the upper end of the blocking layer 911 positioned in the +Z direction may be removed. While removing the second sacrificial layer 9012, the information storage layer 912 may be gradually removed from the upper end (e.g., the top) to the channel hole H. While removing the third sacrificial layer 9013, the blocking layer 911 and the tunneling layer 913 may be gradually removed from the upper end (e.g., the top) to the channel hole H. For example, the gate dielectric layer 910 stacked on the first etch stopper space ES1 may be sequentially removed from the upper end (e.g., top) to the lower end (e.g., bottom) (e.g., the −Z direction) through a butting process. As the butting process proceeds, the gate dielectric layer 910 may be mostly removed from the first etch stopper space ES1, and for example, may be removed up to a position that is lower than (the upper surface of) the intermediate insulating layer 903.

The removal degree of the gate dielectric layer 910 may vary depending on the shape of the channel structure and the time required for the butting process. For example, as shown in FIG. 9D, in the case of the asymmetric channel structure C CH-C, the removal degree of the gate dielectric layer 910 may be different for each part. In the butting process, since the horizontal part 910b extending in the horizontal direction at the upper surface (e.g., the top) of the stacked structure ST is firstly removed, etching portions of the gate dielectric layer 910 positioned in the channel hole H may be prevented while the horizontal part 910b is removed. For example, through the horizontal part 910b, the gate dielectric layer 910 may maintain the vertical length of each part of the gate dielectric layer 910 constant during the butting process or may perform a buffer function to minimize a discrepancy, and through this, the performance degradation of a drain saturation current of each of the channel structures CH-A, CH-B, and CH-C may be minimized or mitigated.

Referring to FIG. 9E, after the gate dielectric layer 910 is sufficiently removed, undoped polysilicon 9021 may be stacked on (the upper surface or the top of) the stacked structure ST. The polysilicon 9021 may (at least partially) fill an area from which the gate dielectric layer 910 is removed, and may be on (e.g., cover or overlap) the upper surface (e.g., the top) of the channel structure CH. The polysilicon 9021 filled in the area from which the gate dielectric layer 910 is removed may contact the outer surface of the exposed channel layer 907 and may extend around (e.g., at least partially enclose) the outer surface of the channel structure CH. The polysilicon 9021 may be connected to the remaining sacrificial poly layer 9022 and may form a source structure 902. For example, the polysilicon 9021 may form a first source part (the first source part 602a of FIG. 6), and the remaining sacrificial poly layer 9022 may form a second source part (the second source part 602b of FIG. 6). In addition, since the polysilicon 9021 and the sacrificial poly layer 9022 are formed during different processes, the polysilicon 9021 and the sacrificial poly layer 9022 may have different crystal structures, and due to the different crystal structures, an interface may be formed between the polysilicon 9021 and the sacrificial poly layer 9022.

Referring to FIG. 9F, the polysilicon 9021 may be doped with p-type impurities. A part (e.g., a polysilicon part 9021N positioned on the upper surface (e.g., the top) of the separation structure MS) of the polysilicon 9021 may be doped with n-type impurities. Thereafter, a cover layer 980 may be stacked on the top of the polysilicon 9021.

The processes of forming a stacked structure, a channel structure, and a source structure of a semiconductor memory device are described with reference to FIGS. 9A, 9B, 9C, 9D, 9E, and 9F, but this is an example. The processes of forming the stacked structure, the channel structure, and the source structure are not limited thereto. For example, in the above description, it shall be noted that some processes may be omitted or modified, an arbitrary process may be added, or the order may be modified.

While this disclosure includes specific examples, it will be apparent to one of ordinary skill in the art that various changes in form and details may be made in these examples without departing from the scope of the claims and their equivalents. The examples described herein are to be considered in a descriptive sense only, and not for purposes of limitation. Descriptions of features or aspects in each example are to be considered as being applicable to similar features or aspects in other examples. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and/or equivalents of the claims are within the scope of the following claims.

What is claimed is:

1. A semiconductor memory device comprising:
a substrate;
a bit line on an upper surface of the substrate;
a stacked structure comprising a plurality of gate electrodes and a plurality of interlayer insulating layers that are alternately stacked in a vertical direction on the bit line;
a source structure on the stacked structure; and
a plurality of channel structures extending in the stacked structure and electrically connecting the source structure to the bit line,
wherein each of the channel structures comprises:
a core insulator in a channel hole that extends in the stacked structure in the vertical direction, wherein the core insulator protrudes into the source structure;
a channel layer extending around the core insulator; and
a gate dielectric layer extending around at least a portion of an outer surface of the channel layer,
wherein a first portion of the gate dielectric layer extends in a horizontal direction on an upper surface of the stacked structure,
wherein the source structure comprises:
a first source part that is in contact with the channel structures; and
a plurality of second source parts spaced apart from the channel structures by the first source part,
wherein the first source part has a different crystal structure from the second source parts,
wherein the horizontal direction is parallel with the upper surface of the substrate, and
wherein the vertical direction is perpendicular to the upper surface of the substrate.

2. The semiconductor memory device of claim 1, wherein the gate dielectric layer further comprises:
a second portion extending in the stacked structure in the vertical direction, and
wherein the first portion includes a first horizontal part that is connected to an upper end of the second portion and extends away from the channel layer in the horizontal direction.

3. The semiconductor memory device of claim 2, wherein the first portion further comprises:
a second horizontal part that is connected to the first horizontal part and extends toward the core insulator in the horizontal direction on the first horizontal part.

4. The semiconductor memory device of claim 3, wherein each of the first horizontal part, the second horizontal part, and the second portion of the gate dielectric layer includes a tunneling layer, an information storage layer, and a blocking layer,
wherein the tunneling layer, the information storage layer, and the blocking layer in the second portion of the gate dielectric layer are sequentially stacked in the horizontal direction on a portion of the core insulator, and
wherein the tunneling layer of the first horizontal part and the tunneling layer of the second horizontal part are stacked in the vertical direction.

5. The semiconductor memory device of claim 1, further comprising:
an intermediate insulating layer disposed between the second source parts and the stacked structure in the vertical direction,
wherein the intermediate insulating layer overlaps the gate electrodes in the vertical direction.

6. The semiconductor memory device of claim 5, wherein the gate dielectric layer extends from the channel layer to the intermediate insulating layer in the horizontal direction on the stacked structure.

7. The semiconductor memory device of claim 5, wherein an interface between the gate dielectric layer and the source structure is coplanar with or closer to the substrate than an upper surface of the intermediate insulating layer in the vertical direction.

8. The semiconductor memory device of claim 5, wherein the first portion of the gate dielectric layer extends in the horizontal direction and contacts with the intermediate insulating layer.

9. The semiconductor memory device of claim 1, wherein upper surfaces of the channel structures are farther than upper surfaces of the second source parts from the upper surface of the substrate in the vertical direction.

10. The semiconductor memory device of claim 1, wherein the core insulator comprises:
a core extension part extending in the channel hole and protruding toward the source structure in the vertical direction; and
a core head part connected to an upper end of the core extension part,
wherein the core head part has a greater width than a width of the core extension part in the horizontal direction, and
wherein the first portion of the gate dielectric layer extends in the horizontal direction between the core head part and the stacked structure.

11. A semiconductor memory device comprising:
a stacked structure comprising a plurality of gate electrodes and a plurality of interlayer insulating layers that are alternately stacked in a vertical direction;
a source structure on the stacked structure; and
a plurality of channel structures extending in the stacked structure,
wherein each of the channel structures comprises:
a core insulator extending in the stacked structure in the vertical direction, wherein the core insulator protrudes into the source structure;
a channel layer extending around the core insulator; and
a gate dielectric layer on an outer surface of the channel layer,
wherein the gate dielectric layer includes a first portion between an upper surface of the stacked structure and the source structure in the vertical direction and a second portion overlapping the stacked structure in a horizontal direction that is perpendicular to the vertical direction,
wherein the source structure comprises:
a first source part that is in contact with the channel structures; and
a plurality of second source parts spaced apart from the channel structures by the first source part,
wherein the first source part extends around the second source parts, and
wherein the first source part has a different crystal structure from the second source parts.

12. The semiconductor memory device of claim 11, further comprising:
an intermediate insulating layer on the stacked structure,
wherein the first portion of the gate dielectric layer extends from the channel layer toward the intermediate insulating layer on the second portion of the gate dielectric layer and the stacked structure.

13. The semiconductor memory device of claim 12, wherein an upper surface of the first portion of the gate dielectric layer is lower than or at a same height as an upper surface of the intermediate insulating layer.

14. The semiconductor memory device of claim 12, wherein the gate dielectric layer further comprises:
a third portion that extends from the intermediate insulating layer toward the channel layer in the horizontal direction on the first portion of the gate dielectric layer.

15. The semiconductor memory device of claim 14, wherein the first portion, the second portion, and the third portion of the gate dielectric layer form a unitary structure.

16. The semiconductor memory device of claim 15, wherein an upper surface of the third portion of the gate dielectric layer is coplanar with an upper surface of the intermediate insulating layer.

17. The semiconductor memory device of claim 11, wherein at least one of the channel structures has an asymmetrical shape in the horizontal direction.

18. The semiconductor memory device of claim 11, further comprising:
an intermediate insulating layer on the stacked structure,
wherein each of the second source parts overlaps the intermediate insulating layer in the vertical direction.

19. An electronic system, comprising:
a semiconductor device that includes an input/output pad electrically connected to a peripheral circuit; and
a controller which controls the semiconductor device and is electrically connected through the input/output pad to the semiconductor device;
wherein the semiconductor device includes:
a substrate;
a bit line on an upper surface of the substrate;
a stacked structure comprising a plurality of gate electrodes and a plurality of interlayer insulating layers that are alternately stacked in a vertical direction on the bit line;
a source structure on the stacked structure; and
a plurality of channel structures extending in the stacked structure and electrically connecting the source structure to the bit line,
wherein each of the channel structures comprises:
a core insulator in a channel hole that extends in the stacked structure in the vertical direction, wherein the core insulator protrudes into the source structure;
a channel layer extending around the core insulator; and
a gate dielectric layer extending around at least a portion of an outer surface of the channel layer,
wherein a first portion of the gate dielectric layer extends in a horizontal direction on an upper surface of the stacked structure,
wherein the source structure comprises:
a first source part that is in contact with the channel structures; and
a plurality of second source parts spaced apart from the channel structures by the first source part,
wherein the first source part has a different crystal structure from the second source parts,
wherein the horizontal direction is parallel with the upper surface of the substrate, and
wherein the vertical direction is perpendicular to the upper surface of the substrate.

20. The electronic system of claim 19, wherein the core insulator comprises:
a core extension part extending in the channel hole and protruding toward the source structure in the vertical direction; and
a core head part connected to an upper end of the core extension part,
wherein the core head part has a greater width than a width of the core extension part in the horizontal direction, and
wherein the first portion of the gate dielectric layer extends in the horizontal direction between the core head part and the stacked structure.
